(19) United States
(12) Patent Application Publication
(10) Pub. No.: US 2025/0385199 A1
(43) Pub. Date: Dec. 18, 2025

(54) ELECTRONIC DEVICE INCLUDING RIGID LAYER AND METHOD FOR MANUFACTURING THE SAME

(71) Applicant: NANYA TECHNOLOGY CORPORATION, NEW TAIPEI CITY (TW)

(72) Inventors: SHING-YIH SHIH, NEW TAIPEI CITY (TW); TSE-YAO HUANG, NEW TAIPEI CITY (TW)

(21) Appl. No.: 18/744,931

(22) Filed: Jun. 17, 2024

(51) Int. Cl. H01L 23/00; H01L 23/31; H01L 23/48; H01L 25/065

(52) U.S. Cl. CPC H01L 23/562; H01L 24/08; H01L 25/0657; H01L 23/3107; H01L 23/481; H01L 24/96; H01L 2224/08145; H01L 2224/96

(57) ABSTRACT

The present application discloses an electronic device and a method for manufacturing the electronic device. The electronic device includes a first semiconductor chip encapsulated by a first encapsulant, a second semiconductor chip encapsulated by a second encapsulant and a first intermediate structure. The second semiconductor chip is disposed over and electrically connected to the first semiconductor chip. The first intermediate structure is interposed between the first semiconductor chip and the second semiconductor chip, and includes a first rigid layer. A periphery portion of the first rigid layer of the first intermediate structure vertically overlaps the first encapsulant and the second encapsulant, and is configured to control a warpage of the electronic device.

### TECHNICAL FIELD

The present disclosure relates to an electronic device and a method for manufacturing the same, and more particularly, to an electronic device including a rigid layer, and a method for manufacturing the same.

### DISCUSSION OF THE BACKGROUND

Semiconductor electronic devices are used in a variety of electronic applications, and the dimensions of package structures are continuously being scaled down to meet the current application requirements. However, a variety of issues arise during the scaling-down process and impact the final electrical characteristics, quality, cost and yield. For example, warpage control.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides an electronic device including a first semiconductor chip, a second semiconductor chip and a first intermediate structure. The first semiconductor chip is encapsulated by a first encapsulant. The second semiconductor chip is disposed over and electrically connected to the first semiconductor chip. The second semiconductor chip is encapsulated by a second encapsulant. The first intermediate structure is interposed between the first semiconductor chip and the second semiconductor chip, and includes a first rigid layer. A periphery portion of the first rigid layer of the first intermediate structure vertically overlaps the first encapsulant and the second encapsulant, and is configured to control a warpage of the electronic device.

Another aspect of the present disclosure provides an electronic device including a first assembly, a second assembly and a metal layer. The first assembly includes a first semiconductor chip and a second semiconductor chip stacked on the first semiconductor chip. The second semiconductor chip is electrically connected to the first semiconductor chip by hybrid bonding. The second assembly includes a third semiconductor chip and a fourth semiconductor chip stacked on the third semiconductor chip. The fourth semiconductor chip is electrically connected to the third semiconductor chip by hybrid bonding. The metal layer is interposed between the first assembly and the second assembly. A periphery portion of the metal layer directly contacts an encapsulant of the first assembly and an encapsulant of the second assembly.

Another aspect of the present disclosure provides a method for manufacturing an electronic device including: providing a first semiconductor chip; forming a first encapsulant to encapsulate the first semiconductor chip; forming a first intermediate structure on the first semiconductor chip and the first encapsulant; providing a second semiconductor chip on the first intermediate structure; and forming a second encapsulant on the first intermediate structure to encapsulate the second semiconductor chip.

Due to the design of the electronic device of the present disclosure, the first rigid layer or the metal layer are configured to control or reduce the warpage of the electronic device. As a result, the bonding between the first semiconductor chip and the second semiconductor chip, or the bonding between the first assembly and the second assembly is enhanced. The risk of delamination between the first semiconductor chip and the second semiconductor chip, or the risk of delamination between the first assembly and the second assembly is reduced. Therefore, the reliability and working life of the electronic device is improved.

The foregoing has outlined rather broadly the features and technical advantages of the present disclosure in order that the detailed description of the disclosure that follows may be better understood. Additional features and advantages of the disclosure will be described hereinafter and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

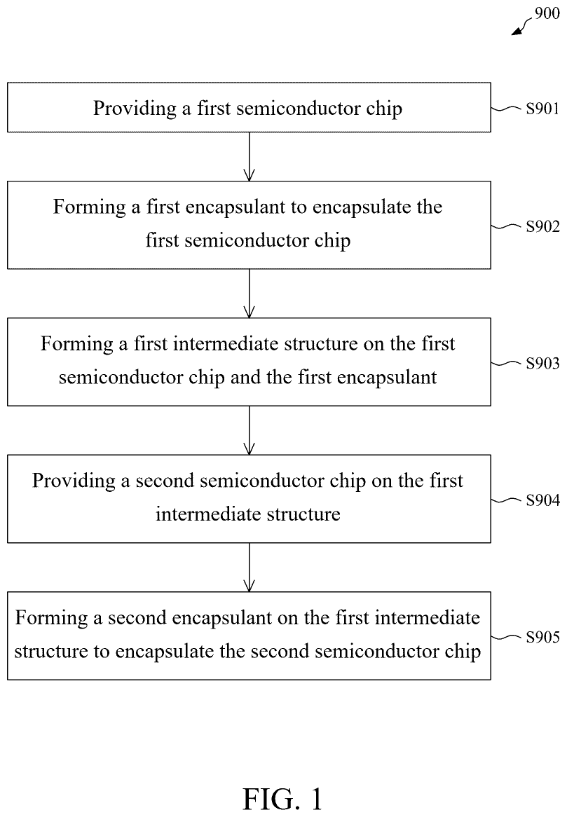

FIG. 1 illustrates, in a flowchart diagram form, a method for manufacturing an electronic device in accordance with one embodiment of the present disclosure.

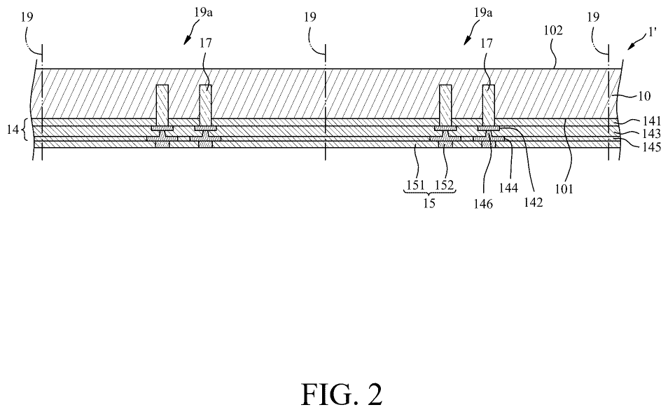

FIGS. 2 to 18 illustrate, in schematic cross-sectional view diagrams, a flow for manufacturing an electronic device in accordance with one embodiment of the present disclosure.

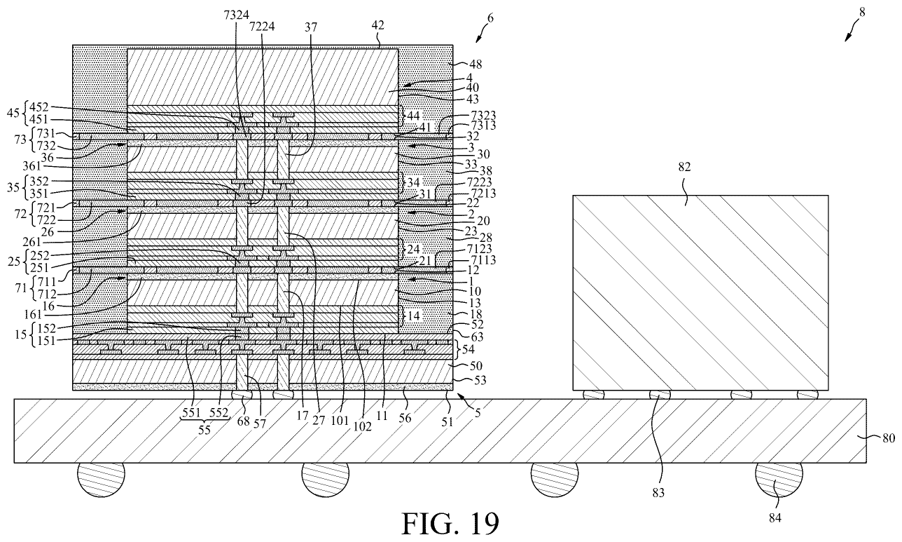

FIG. 19 illustrates, in a schematic cross-sectional view diagram, a semiconductor structure in accordance with one embodiment of the present disclosure.

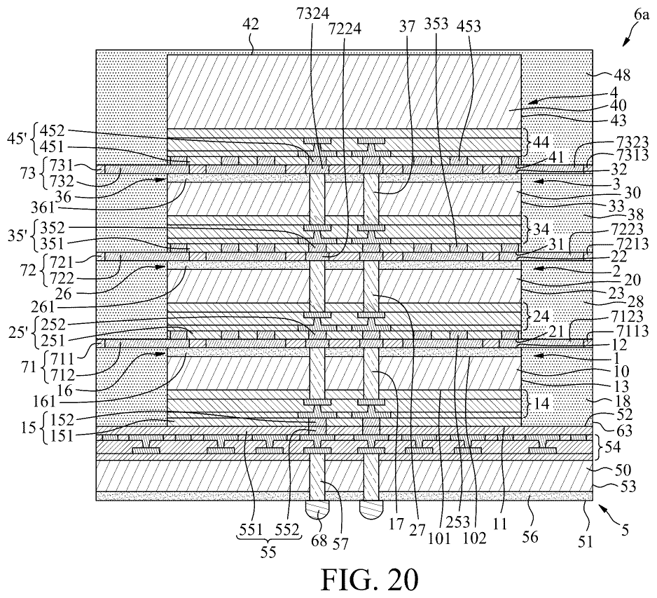

FIG. 20 illustrates, in a schematic cross-sectional view diagram, an electronic device in accordance with one embodiment of the present disclosure.

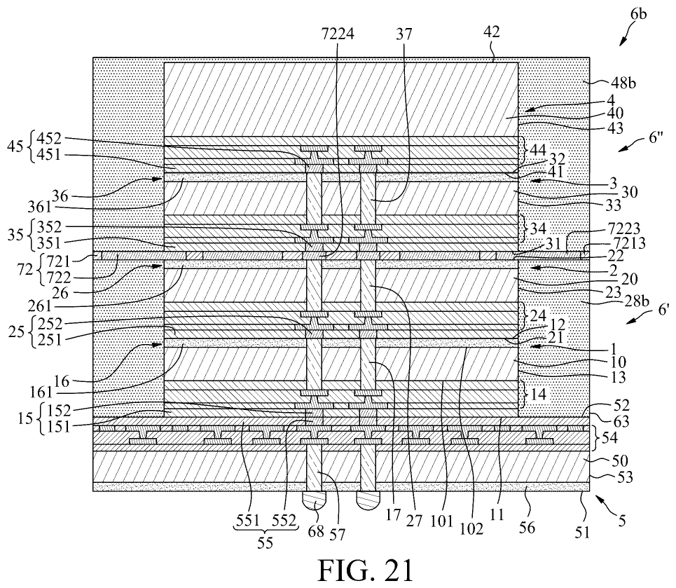

FIG. 21 illustrates, in a schematic cross-sectional view diagram, an electronic device in accordance with one embodiment of the present disclosure.

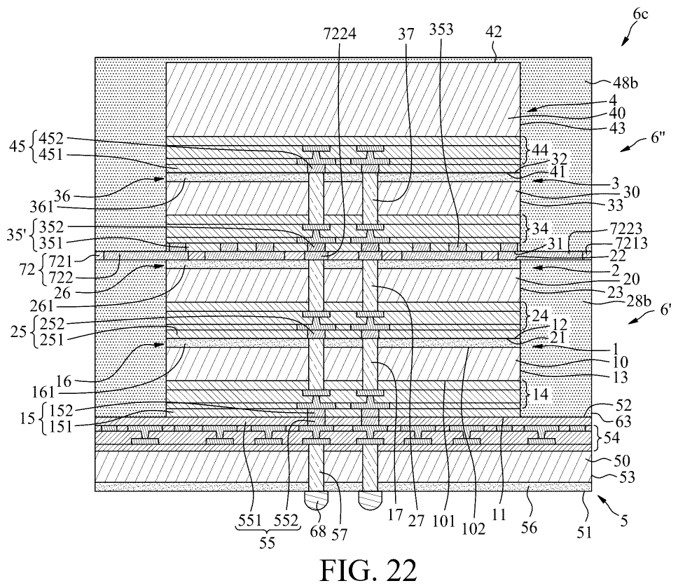

FIG. 22 illustrates, in a schematic cross-sectional view diagram, an electronic device in accordance with one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a package structure, an electronic device, a semiconductor electronic device or a semiconductor electronic structure may generally mean a device which can function by utilizing semiconductor characteristics.

FIG. 1 illustrates, in a flowchart diagram form, a method 900 for manufacturing an electronic device 6 in accordance with one embodiment of the present disclosure. FIGS. 2 to 18 illustrate, in schematic cross-sectional view diagrams, a flow for manufacturing the electronic device 6 in accordance with one embodiment of the present disclosure.

With reference to FIGS. 2 to 6, at step S901, a first semiconductor chip 1 may be provided.

With reference to FIG. 2, a first wafer 1′ may be provided. The first wafer 1′ may include a first base portion 10, a first conductive structure 14, a first lower structure 15 and a plurality of first conductive vias 17. The first wafer 1′ may have a plurality of singulation lines 19 to define a plurality of units 19a. The first base portion 10 may have a first surface 101 (e.g., a bottom surface) and a second surface 102 (e.g., a top surface) opposite to the first surface 101.

The first base portion 10 may be a semiconductor substrate, and may include, for example, silicon (Si), doped silicon, germanium (Ge), silicon germanium (SiGe), silicon carbide (SIC), silicon germanium carbide (SiGeC), gallium (Ga), gallium arsenide (GaAs), indium (In), indium arsenide (InAs), indium phosphide (InP) or other IV-IV, III-V or II-VI semiconductor materials, or combinations thereof. In some embodiments, the first base portion 10 may include a semiconductor-on-insulator substrate, such as a silicon-on-insulator (SOI) substrate, a silicon germanium-on-insulator (SGOI) substrate, or a germanium-on-insulator (GOI) substrate. In some embodiments, the first base portion 10 may be a bulk semiconductor substrate that is composed entirely of at least one semiconductor material; the bulk semiconductor substrate does not contain any dielectrics, insulating layers, or conductive features.

The first conductive structure 14 may be disposed on the first surface 101 (e.g., the bottom surface) of the first base portion 10. In some embodiments, the first conductive structure 14 may include a plurality of front-end-of-line (FEOL) devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof. In some embodiments, the first conductive structure 14 may further include at least one back-end-of-line (BEOL) interconnect pattern, e.g., a plurality of patterned circuit layers, electrically connected to the front-end-of-line (FEOL) devices. In some embodiments, the first conductive structure 14 may further include at least one dielectric layer or passivation layer or at least one dielectric structure covering the front-end-of-line (FEOL) devices and the back-end-of-line (BEOL) interconnect pattern.

The first conductive structure 14 may include a first dielectric layer 141, a first circuit layer (including a plurality traces and a plurality of pads 142), a second dielectric layer 143, a second circuit layer (including a plurality trace and a plurality of pads 144), a plurality of inner vias 146 and a third dielectric layer 145. The first dielectric layer 141 may be disposed on the first surface 101 (e.g., a bottom surface) of the first base portion 10. The first dielectric layer 141 may be an interlayer dielectric (ILD) layer, and may include SiO₂, SiN, and/or SiCN. The first circuit layer (including the traces and the pads 142) may be disposed on the first dielectric layer 141.

The second dielectric layer 143 may be disposed on the first dielectric layer 141 to cover the first circuit layer. The second dielectric layer 143 may be an inter-metal dielectric (IMD) layer, and may include SiO₂, SiN, and/or SiCN. The second circuit layer (including the traces and the pads 144) may be disposed on the second dielectric layer 143.

The inner vias 146 may be disposed in the second dielectric layer 143, and may connect the first circuit layer (e.g., the pads 142) and the second circuit layer (e.g., the pads 144). The third dielectric layer 145 may surround the second circuit layer (e.g., the pads 144). The third dielectric layer 145 may include SiO₂, SiN, and/or SiCN.

The first lower structure 15 may be disposed on the first conductive structure 14. The first lower structure 15 may include a first lower dielectric layer 151 and a plurality of first lower pads 152. The first lower pads 152 may be disposed on the second circuit layer (e.g., the pads 144), and may be embedded in the first lower dielectric layer 151. Each of the first lower pads 152 may be a hybrid bonding (HB) pad and may include Cu or Al. The first lower pads 152 may be exposed by the first lower dielectric layer 151. The first lower dielectric layer 151 may be a hybrid bonding (HB) dielectric layer, and may include SiO₂, SiN, and/or SiCN.

The first conductive vias 17 may be disposed in the first base portion 10, and may extend beyond the first surface 101 (e.g., the bottom surface) of the first base portion 10. The first conductive vias 17 may extend through the first dielectric layer 141 to connect or contact the first circuit layer (e.g., the pads 142). Thus, the first conductive vias 17 may extend into the first conductive structure 14, and may be electrically connected to the first conductive structure 14. Thus, the first lower pads 152 may be electrically connected to the first conductive vias 17 through the first conductive structure 14.

In each of the units 19a, the first conductive vias 17 may be disposed at a center portion of the unit 19a. In some embodiments, the first conductive vias 17 may be configured for signal transmission. In some embodiments, some of the first conductive vias 17 may be disposed at a periphery portion of the unit 19a for heat dissipation.

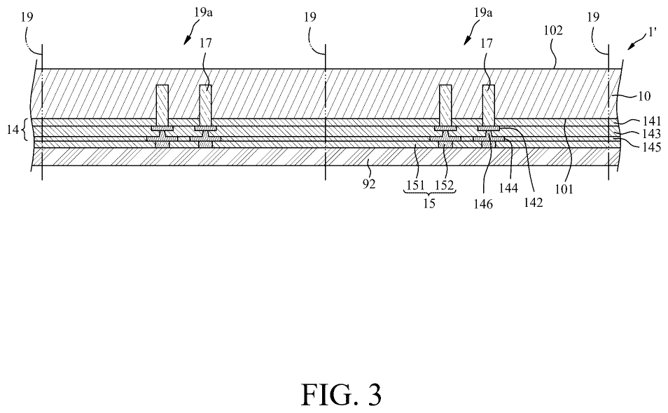

With reference to FIG. 3, the first wafer 1′ may be attached to or bonded to a carrier 92. The first lower structure 15 of the first wafer 1′ may contact the carrier 92. Thus, the first surface 101 (e.g., a bottom surface) of the first base portion 10 may face the carrier 92.

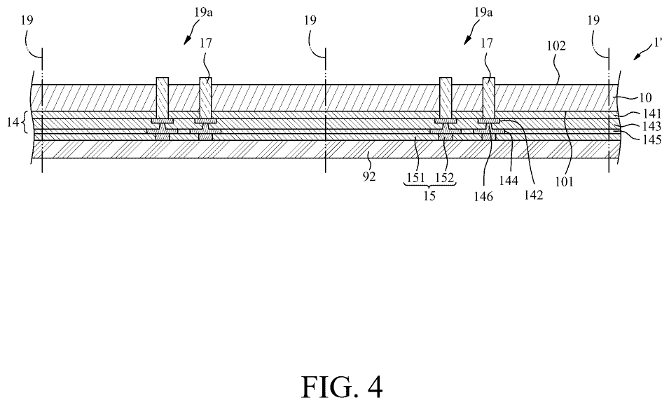

With reference to FIG. 4, the first base portion 10 may be thinned from its second surface 102 (e.g., the top surface) by grinding, chemical-mechanical polishing (CMP) and dry etching, so as to expose the first conductive vias 17. Thus, the first conductive vias 17 may extend beyond the second surface 102 (e.g., the top surface) of the first base portion 10. The first conductive vias 17 may extend through the first base portion 10.

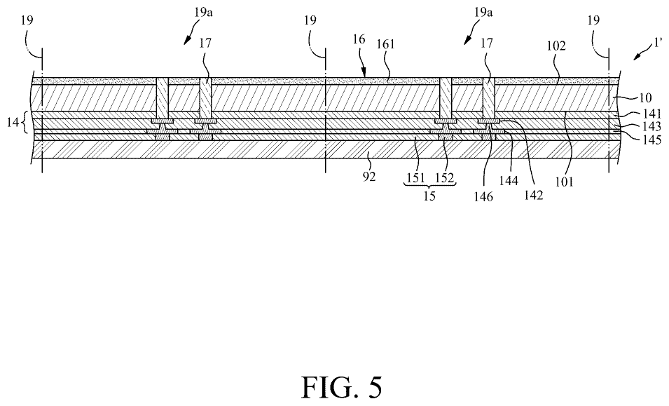

With reference to FIG. 5, a first upper structure 16 may be formed on the second surface 102 (e.g., the top surface) of the first base portion 10. The first upper structure 16 may include a first upper dielectric layer 161 and other suitable elements. The first upper dielectric layer 161 may be disposed on the second surface 102 (e.g., the top surface) of the first base portion 10, and may cover a top portion of the first conductive via 17. The first upper dielectric layer 161 may be a hybrid bonding (HB) dielectric layer, and may include SiO₂, SiN, and/or SiCN.

Then, the first upper structure 16 (e.g., the first upper dielectric layer 161) may be thinned from its top surface by, for example, chemical-mechanical polishing (CMP), so as to expose the first conductive vias 17. Thus, the top surface of the first upper structure 16 (e.g., the first upper dielectric layer 161) may be substantially aligned with the top surfaces of the first conductive vias 17. The first conductive vias 17 may extend through the first upper structure 16 (e.g., the first upper dielectric layer 161).

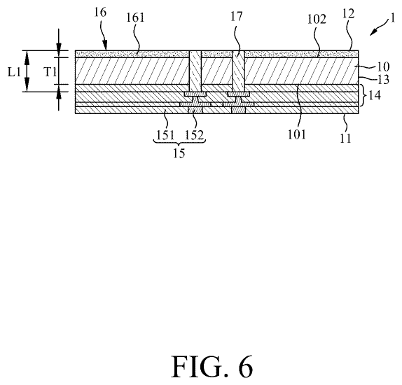

With reference to FIG. 6, the carrier 92 may be removed from the first wafer 1′. Then, the first wafer 1′ may be singulated along the singulation lines 19 to form a plurality of first semiconductor chips 1. Each of the first semiconductor chips 1 corresponds to each of the units 19a. The first semiconductor chip 1 has a first surface 11 (e.g., a bottom surface), a second surface 12 (e.g., a top surface) and a lateral surface 13 extending between the first surface 11 (e.g., the bottom surface) and the second surface 12 (e.g., the top surface). A length L1 of the first conductive via 17 may be greater than a thickness T1 of the first base portion 10.

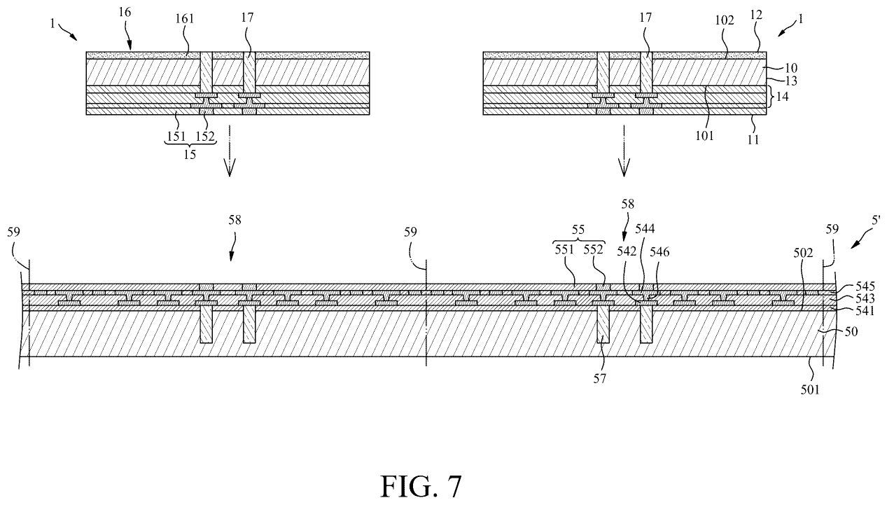

With reference to FIGS. 7 to 9, at step S902, a first encapsulant 18 may be formed to encapsulate the first semiconductor chip 1. With reference to FIG. 7, a fifth wafer 5′ may be provided. The fifth wafer 5′ may include a fifth base portion 50, a fifth conductive structure 54, a fifth upper structure 55 and a plurality of fifth conductive vias 57. The fifth wafer 5′ may have a plurality of singulation lines 59 to define a plurality of units 58. The fifth base portion 50 may have a first surface 501 (e.g., a bottom surface) and a second surface 502 (e.g., a top surface) opposite to the first surface 501.

The fifth base portion 50 may be a semiconductor substrate, and may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials, or combinations thereof. In some embodiments, the fifth base portion 50 may include a semiconductor-on-insulator substrate, such as a silicon-on-insulator

(SOI) substrate, a silicon germanium-on-insulator (SGOI) substrate, or a germanium-on-insulator (GOI) substrate. In some embodiments, the fifth base portion 50 may be a bulk semiconductor substrate that is composed entirely of at least one semiconductor material; the bulk semiconductor substrate does not contain any dielectrics, insulating layers, or conductive features.

The fifth conductive structure 54 may be disposed on the second surface 502 (e.g., the top surface) of the fifth base portion 50. In some embodiments, the fifth conductive structure 54 may include a plurality of front-end-of-line (FEOL) devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof. In some embodiments, the fifth conductive structure 54 may further include at least one back-end-of-line (BEOL) interconnect pattern, e.g., a plurality of patterned circuit layers, electrically connected to the front-end-of-line (FEOL) devices. In some embodiments, the fifth conductive structure 54 may further include at least one dielectric layer or passivation layer or at least one dielectric structure covering the front-end-of-line (FEOL) devices and the back-end-of-line (BEOL) interconnect pattern.

The fifth conductive structure 54 may include a first dielectric layer 541, a first circuit layer (including a plurality traces and a plurality of pads 542), a second dielectric layer 543, a second circuit layer (including a plurality trace and a plurality of pads 544), a plurality of inner vias 546 and a third dielectric layer 545. The first dielectric layer 541 may be disposed on the second surface 502 (e.g., the top surface) of the fifth base portion 50. The first dielectric layer 541 may be an interlayer dielectric (ILD) layer, and may include SiO₂, SiN, and/or SiCN. The first circuit layer (including the traces and the pads 542) may be disposed on the first dielectric layer 541.

The second dielectric layer 543 may be disposed on the first dielectric layer 541 to cover the first circuit layer. The second dielectric layer 543 may be an inter-metal dielectric (IMD) layer, and may include SiO₂, SiN, and/or SiCN. The second circuit layer (including the traces and the pads 544) may be disposed on the second dielectric layer 543.

The inner vias 546 may be disposed in the second dielectric layer 543, and may connect the first circuit layer (e.g., the pads 542) and the second circuit layer (e.g., the pads 544). The third dielectric layer 545 may surround the second circuit layer (e.g., the pads 544). The third dielectric layer 545 may include SiO₂, SiN, and/or SiCN.

The fifth upper structure 55 may be disposed on the fifth conductive structure 54. The fifth upper structure 55 may include a fifth upper dielectric layer 551 and a plurality of fifth upper pads 552. The fifth upper pads 552 may be disposed on the second circuit layer (e.g., the pads 544), and may be embedded in the fifth upper dielectric layer 551. Each of the fifth upper pads 552 may be a hybrid bonding (HB) pad and may include Cu or Al. The fifth upper pads 552 may be exposed by the fifth upper dielectric layer 551. The fifth upper dielectric layer 551 may be a hybrid bonding (HB) dielectric layer, and may include SiO₂, SiN, and/or SiCN.

The fifth conductive vias 57 may be disposed in the fifth base portion 50, and may extend beyond the second surface 502 (e.g., the top surface) of the fifth base portion 50. The fifth conductive vias 57 may extend through the first dielectric layer 541 to connect or contact the first circuit layer (e.g., the pads 542). Thus, the fifth conductive vias 57 may extend into the fifth conductive structure 54, and may be electrically connected to the fifth conductive structure 54. Thus, the fifth upper pads 552 may be electrically connected to the fifth conductive vias 57 through the fifth conductive structure 54.

In each of the units 58, the fifth conductive vias 57 may be disposed at a center portion of the unit 58. In some embodiments, the fifth center vias 571 may be configured for signal transmission. In some embodiments, some of the fifth conductive vias 57 may be disposed at a periphery portion of the unit 58 for heat dissipation.

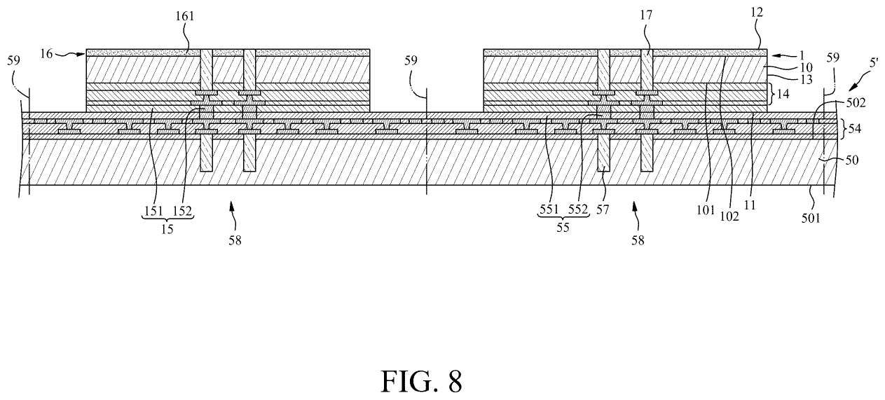

With reference to FIG. 8, a plurality of first semiconductor chips 1 may be attached to the units 58 of the fifth wafer 5′ by hybrid bonding. The first surface 11 of the first semiconductor chip 1 may directly contact the fifth upper structure 55 of the fifth wafer 5′. The first lower dielectric layer 151 of the first lower structure 15 of the first semiconductor chip 1 may be adhered to the fifth upper dielectric layer 551 of the fifth upper structure 55 of the fifth wafer 5′. The first lower pads 152 of the first lower structure 15 of the first semiconductor chip 1 may be attached to the fifth upper pads 552 of the fifth upper structure 55 of the fifth wafer 5′ by metal-to-metal bonding.

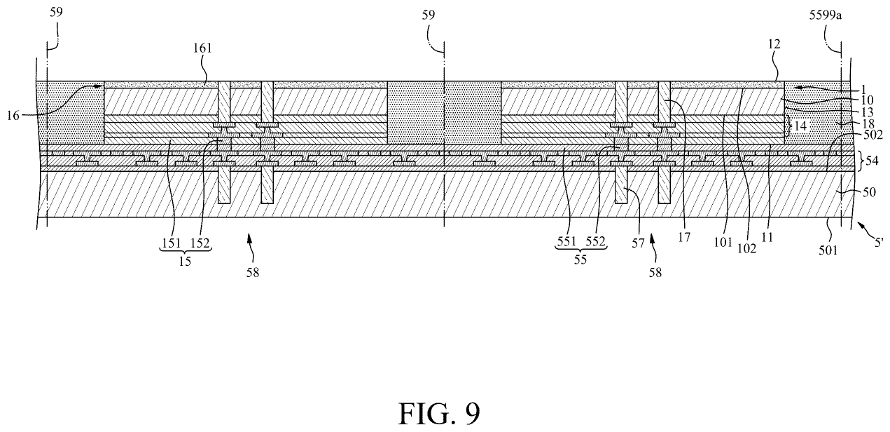

With reference to FIG. 9, a first encapsulant 18 may be formed or disposed on the top surface of the fifth wafer 5′ to encapsulate the first semiconductor chips 1. Thus, the first semiconductor chip 1 may be encapsulated by the first encapsulant 18. A material of the first encapsulant 18 may include a molding compound with or without fillers. The first encapsulant 18 may cover and contact the lateral surface 13 of the first semiconductor chip 1 (including the lateral surface of 10 of the first base portion 10, the lateral surface of the first conductive structure 14, the lateral surface of the first lower structure 15 and the lateral surface of the first upper structure 16 (e.g., the first upper dielectric layer 161)).

Then, the first encapsulant 18 may be thinned and planarized from its top surface by, for example, chemical-mechanical polishing (CMP), so as to expose the first conductive vias 17 and the second surface 12 (e.g., the top surface) of the first semiconductor chip 1 or a top surface of the first upper structure 16 (e.g., the first upper dielectric layer 161). Thus, the top surface of the first encapsulant 18 may be substantially aligned with the second surface 12 (e.g., the top surface) of the first semiconductor chip 1 or the top surface of the first upper structure 16 (e.g., the first upper dielectric layer 161) and the top surfaces of the first conductive vias 17.

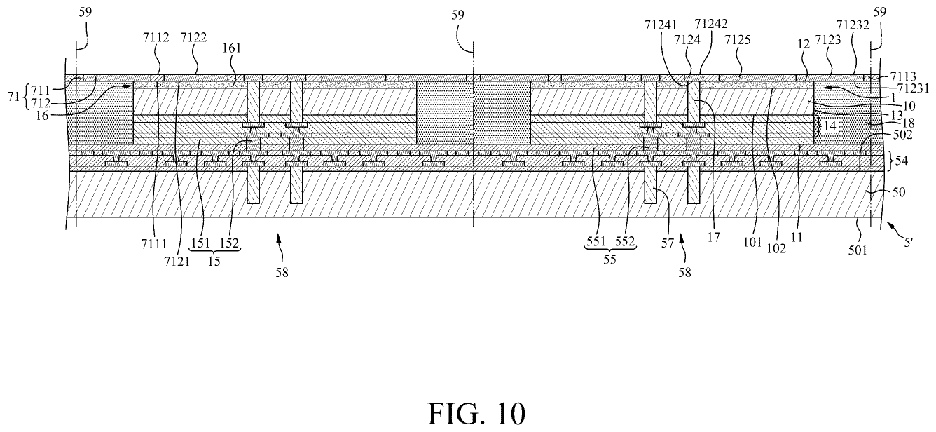

With reference to FIGS. 10, at step S903, a first intermediate structure 71 may be formed or disposed on the first upper structure 16 (e.g., the first upper dielectric layer 161) of the first semiconductor chip 1 and the first encapsulant 18. The first intermediate structure 71 may include a dielectric layer 711 and a first rigid layer 712. The dielectric layer 711 may be a hybrid bonding (HB) dielectric layer, and may include SiO₂, SiN, and/or SiCN. The dielectric layer 711 may encapsulate the first rigid layer 712. A material of the first rigid layer 712 of the first intermediate structure 71 may include metal such as copper (Cu). Thus, the first rigid layer 712 may be also referred to as “a metal layer”. In addition, the first rigid layer 712 may be also referred to as “a reinforcement layer” or “a warpage control layer” or “an intermediate layer”.

A top surface 7112 of the dielectric layer 711 may be substantially level with a top surface 7122 of the first rigid layer 712. A bottom surface 7111 of the dielectric layer 711 may be substantially level with a bottom surface 7121 of the first rigid layer 712. A thickness of the dielectric layer 711 may be equal to a thickness of the first rigid layer 712.

In some embodiments, the dielectric layer 711 may be formed on and may cover the first semiconductor chips 1 and the first encapsulant 18 by, for example, deposition. Then, the dielectric layer 711 may be patterned to form a plurality of openings to expose a plurality of portions of the first semiconductor chips 1 and the first encapsulant 18. Then, the first rigid layer 712 may be formed in the openings to contact the exposed portions of the first semiconductor chips 1 and the first encapsulant 18 by, for example, deposition or electroplating.

The first rigid layer 712 may include a plurality of hybrid bonding pads 7124, a middle portion 7125 and a periphery portion 7123.

The hybrid bonding pads 7124 may be disposed on the first conductive vias 17 for electrical connection. The hybrid bonding pads 7124 may directly contact the first conductive vias 17. Thus, the first conductive vias 17 may be electrically connected to the first rigid layer 712 of the first intermediate structure 71.

The middle portion 7125 and the periphery portion 7123 may surround the hybrid bonding pads 7124. The middle portion 7125 may be disposed between the hybrid bonding pads 7124 and the periphery portion 7123. The periphery portion 7123 may extend beyond the lateral surface 13 of the first semiconductor chip 1. Thus, the periphery portion 7123 may vertically overlap or may directly contact the first upper structure 16 (e.g., the first upper dielectric layer 161) and the first encapsulant 18. The middle portion 7125 and the periphery portion 7123 may be dummy. That is, the middle portion 7125 and the periphery portion 7123 may have no electrical function.

In some embodiments, the periphery portion 7123 and the hybrid bonding pads 7124 may be formed concurrently, and they may be at a same layer. A top surface 71232 of the periphery portion 7123 may be substantially level with a top surface 71242 of the hybrid bonding pad 7124. A bottom surface 71231 of the periphery portion 7123 may be substantially level with a bottom surface 71241 of the hybrid bonding pad 7124. A thickness of the periphery portion 7123 may be substantially equal to a thickness of the hybrid bonding pad 7124. In addition, the dielectric layer 711 may include an outer portion 7113 surrounding the periphery portion 7123 and directly contacting the first encapsulant 18.

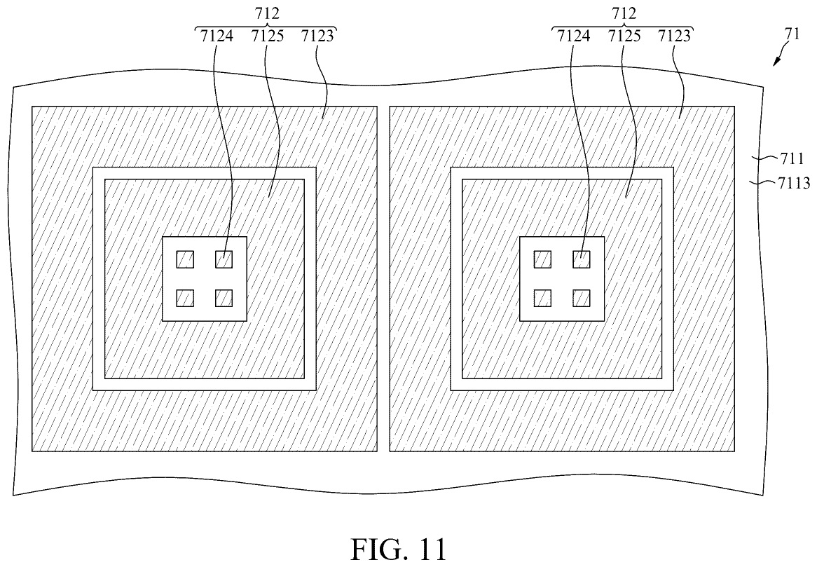

With reference to FIG. 11, a top view of the first intermediate structure 71 of FIG. 10 according to an embodiment is illustrated. Each of the middle portion 7125 and the periphery portion 7123 of the first rigid layer 712 may be in a ring shape.

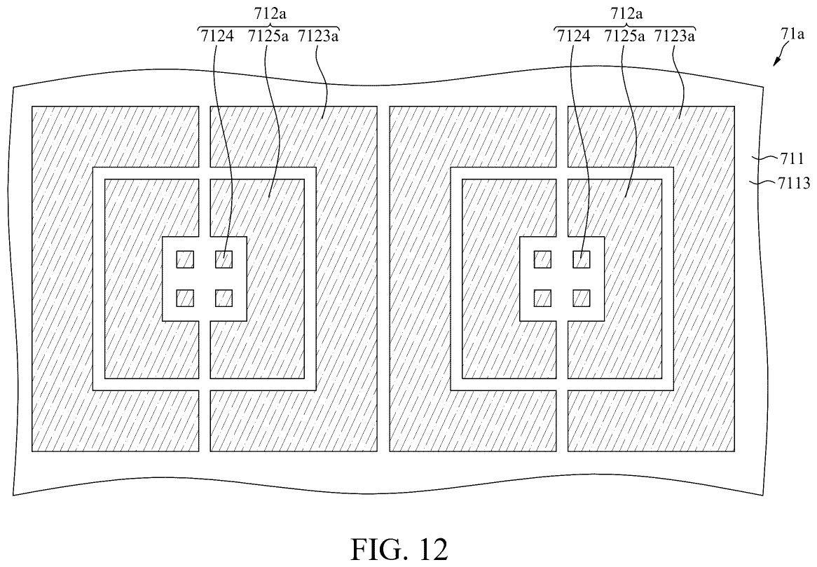

With reference to FIG. 12, a top view of a first intermediate structure 71a according to another embodiment is illustrated. Each of the middle portion 7125a and the periphery portion 7123a of the first rigid layer 712a may include two C-shaped sections.

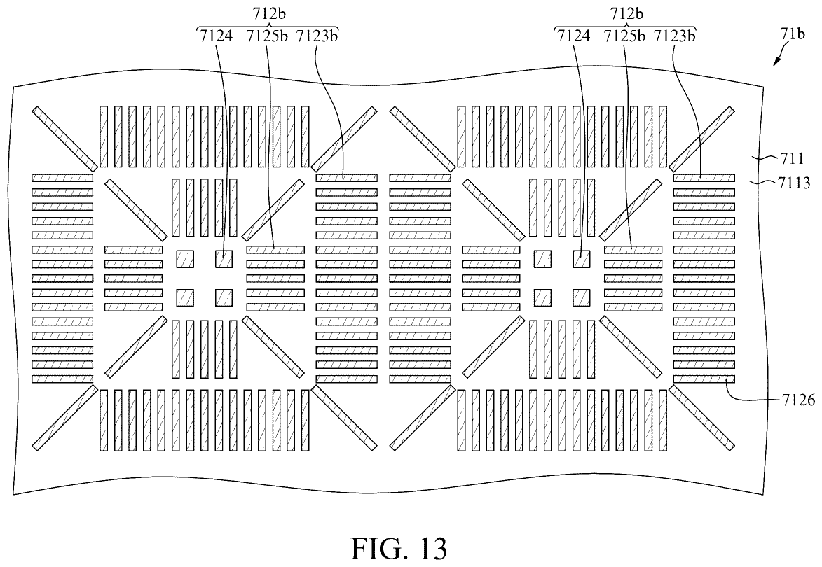

With reference to FIG. 13, a top view of a first intermediate structure 71b according to another embodiment is illustrated. Each of the middle portion 7125b and the periphery portion 7123b of the first rigid layer 712b may include a plurality sections 7126 arranged in a plurality of rows. Each of the sections 7126 may be a strip or a line.

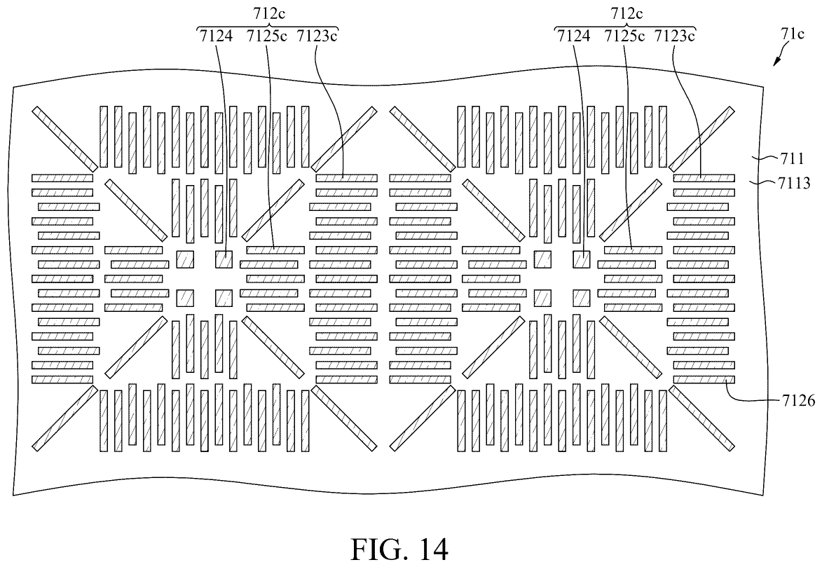

With reference to FIG. 14, a top view of a first intermediate structure 71c according to another embodiment is illustrated. Each of the middle portion 7125c and the periphery portion 7123c of the first rigid layer 712c may include a plurality sections 7126 arranged in a staggered manner. Each of the sections 7126 may be a strip or a line.

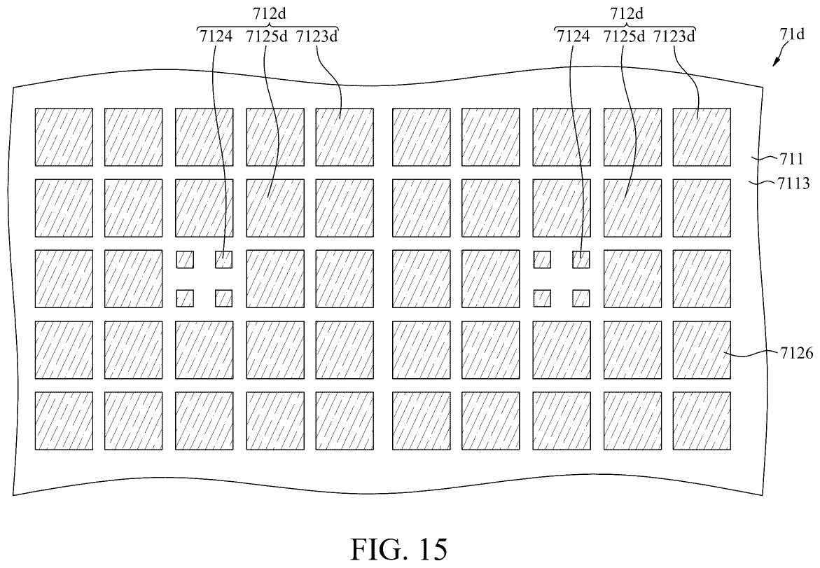

With reference to FIG. 15, a top view of a first intermediate structure 71d according to another embodiment is illustrated. Each of the middle portion 7125d and the periphery portion 7123d of the first rigid layer 712d may include a plurality sections 7126 arranged in an array. Each of the sections 7126 may have a square shape.

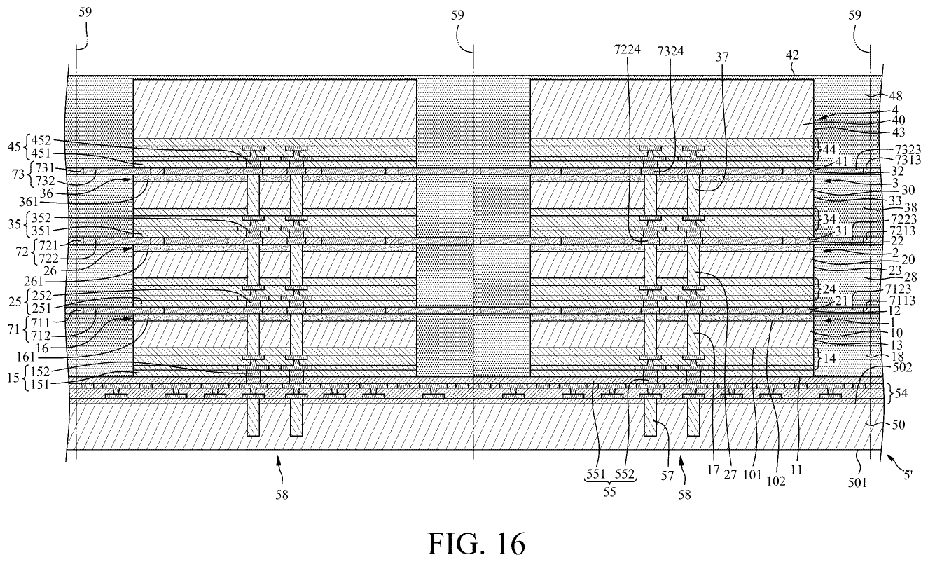

With reference to FIG. 16, at step S904, a second semiconductor chip 2 may be provided on the first intermediate structure 71. In addition, step S905, a second encapsulant 28 may be formed on the first intermediate structure 71 to encapsulate the second semiconductor chip 2. In some embodiments, a plurality of second semiconductor chips 2 may be attached to or electrically connected to the first semiconductor chips 1 by hybrid bonding through the hybrid bonding pads 7124 of the first intermediate structure 71. The structure of the second semiconductor chip 2 may be same as or similar to the structure of the first semiconductor chip 1. The second semiconductor chip 2 has a first surface 21 (e.g., a bottom surface), a second surface 22 (e.g., a top surface) and a lateral surface 23 extending between the first surface 21 (e.g., the bottom surface) and the second surface 22 (e.g., the top surface).

The second semiconductor chip 2 may include a second base portion 20, a second conductive structure 24, a second lower structure 25, a second upper structure 26 and a plurality of second conductive vias 27 that are same as the first base portion 10, the first conductive structure 14, the first lower structure 15, the first upper structure 16 and the first conductive vias 17 of the first semiconductor chip 1, respectively.

The second conductive vias 27 may be disposed at a center portion of the second semiconductor chip 2 for signal transmission. In some embodiments, some of the second conductive vias 27 may be disposed at a periphery portion of the second semiconductor chip 2 for heat dissipation.

The first surface 21 of the second semiconductor chip 2 may directly contact the first intermediate structure 71. The second lower dielectric layer 251 of the second lower structure 25 of the second semiconductor chip 2 may be adhered to the dielectric layer 711 of the first intermediate structure 71. The second lower pads 252 of the second lower structure 25 of the second semiconductor chip 2 may be attached to the hybrid bonding pads 7124 of the first intermediate structure 71 by metal-to-metal bonding. Thus, the hybrid bonding pads 7124 of the first intermediate structure 71 physically connect and electrically connect the first semiconductor chip 1 and the second semiconductor chip 2.

Then, a second encapsulant 28 may be formed or disposed on the top surface of the first intermediate structure 71 to encapsulate the second semiconductor chips 2. Thus, the second semiconductor chip 2 may be encapsulated by the second encapsulant 28. A material of the second encapsulant 28 may include a molding compound with or without fillers. The second encapsulant 28 may cover and contact the lateral surface 23 of the second semiconductor chip 2.

Meanwhile, the second semiconductor chip 2 is disposed over the first semiconductor chip 1. The first intermediate structure 71 is interposed between the first semiconductor chip 1 and the second semiconductor chip 2, and between the first encapsulant 18 and the second encapsulant 28. The periphery portion 7123 of the first rigid layer 712 may vertically overlap the first encapsulant 18 and the second encapsulant 28, and is configured to control a warpage of the electronic device 6. The periphery portion 7123 of the first rigid layer 712 may directly contact the first encapsulant 18 and the second encapsulant 28. In addition, the outer portion 7113 of the dielectric layer 711 may directly contact the first encapsulant 18 and the second encapsulant 28.

Then, the second encapsulant 28 may be thinned and planarized from its top surface by, for example, chemical-mechanical polishing (CMP). Then, a second intermediate structure 72 may be formed or disposed on the second upper structure 26 (e.g., the second upper dielectric layer 261) of the second semiconductor chip 2 and the second encapsulant 28. The second intermediate structure 72 may include a dielectric layer 721 and a second rigid layer 722. The dielectric layer 721 and the second rigid layer 722 may be same as the dielectric layer 711 and the first rigid layer 712 of the first intermediate structure 71. A material of the second rigid layer 722 of the second intermediate structure 72 may include metal.

The second rigid layer 722 may include a plurality of hybrid bonding pads 7224, a middle portion and a periphery portion 7223. The hybrid bonding pads 7224 of the second rigid layer 722 may be disposed on the second conductive vias 27 for electrical connection. The hybrid bonding pads 7224 of the second rigid layer 722 may directly contact the second conductive vias 27. Thus, the second conductive vias 27 may be electrically connected to the second rigid layer 722 of the second intermediate structure 72.

The middle portion and the periphery portion 7223 may surround the hybrid bonding pads 7224. The periphery portion 7223 may extend beyond the lateral surface 23 of the second semiconductor chip 2. Thus, the periphery portion 7223 may vertically overlap or may directly contact the second upper structure 26 (e.g., the second upper dielectric layer 261) and the second encapsulant 28. The middle portion and the periphery portion 7223 may be dummy. That is, the middle portion and the periphery portion 7223 may have no electrical function.

Then, a plurality of third semiconductor chips 3 may be attached to or electrically connected to the second semiconductor chips 2 by hybrid bonding through the hybrid bonding pads 7224 of the second intermediate structure 72. The structure of the third semiconductor chip 3 may be same as or similar to the structure of the first semiconductor chip 1. The third semiconductor chip 3 has a first surface 31 (e.g., a bottom surface), a second surface 32 (e.g., a top surface) and a lateral surface 33 extending between the first surface 31 (e.g., the bottom surface) and the second surface 32 (e.g., the top surface).

The third semiconductor chip 3 may include a third base portion 30, a third conductive structure 34, a third lower structure 35, a third upper structure 36 and a plurality of third conductive vias 37 that are same as the first base portion 10, the first conductive structure 14, the first lower structure 15, the first upper structure 16 and the first conductive vias 17 of the first semiconductor chip 1, respectively.

The third conductive vias 37 may be disposed at a center portion of the third semiconductor chip 3 for signal transmission. In some embodiments, some of the third conductive vias 37 may be disposed at a periphery portion of the third semiconductor chip 3 for heat dissipation.

The first surface 31 of the third semiconductor chip 3 may directly contact the second intermediate structure 72. The third lower dielectric layer 351 of the third lower structure 35 of the third semiconductor chip 3 may be adhered to the dielectric layer 721 of the second intermediate structure 72. The third lower pads 352 of the third lower structure 35 of the third semiconductor chip 3 may be attached to the hybrid bonding pads 7224 of the second intermediate structure 72 by metal-to-metal bonding. Thus, the hybrid bonding pads of the second intermediate structure 72 physically connect and electrically connect the second semiconductor chip 2 and the third semiconductor chip 3.

Then, a third encapsulant 38 may be formed or disposed on the top surface of the second intermediate structure 72 to encapsulate the third semiconductor chips 3. Thus, the third semiconductor chip 3 may be encapsulated by the third encapsulant 38. A material of the third encapsulant 38 may include a molding compound with or without fillers. The third encapsulant 38 may cover and contact the lateral surface 33 of the third semiconductor chip 3.

Meanwhile, the third semiconductor chip 3 is disposed over the second semiconductor chip 2. The second intermediate structure 72 is interposed between the third semiconductor chip 3 and the second semiconductor chip 2, and between the second encapsulant 28 and the third encapsulant 38. The periphery portion 7223 of the second rigid layer 722 may vertically overlap the second encapsulant 28 and the third encapsulant 38, and is configured to control a warpage of the electronic device 6. The periphery portion 7223 of the second rigid layer 722 may directly contact the second encapsulant 28 and the third encapsulant 38. In addition, the outer portion 7213 of the dielectric layer 721 may directly contact the second encapsulant 28 and the third encapsulant 38.

Then, the third encapsulant 38 may be thinned and planarized from its top surface by, for example, chemical-mechanical polishing (CMP). Then, a third intermediate structure 73 may be formed or disposed on the third upper structure 36 (e.g., the third upper dielectric layer 361) of the third semiconductor chip 3 and the third encapsulant 38. The third intermediate structure 73 may include a dielectric layer 731 and a third rigid layer 732. The dielectric layer 731 and the third rigid layer 732 may be same as the dielectric layer 711 and the first rigid layer 712 of the first intermediate structure 71. A material of the third rigid layer 732 of the third intermediate structure 73 may include metal.

The third rigid layer 732 may include a plurality of hybrid bonding pads 7324, a middle portion and a periphery portion 7323. The hybrid bonding pads 7324 of the third rigid layer 732 may be disposed on the third conductive vias 37 for electrical connection. The hybrid bonding pads 7324 of the third rigid layer 732 may directly contact the third conductive vias 37. Thus, the third conductive vias 37 may be electrically connected to the third rigid layer 732 of the third intermediate structure 73.

Then, a plurality of fourth semiconductor chips 4 may be attached to the third intermediate structure 73 by hybrid bonding through the hybrid bonding pads 7324 of the third intermediate structure 73. The structure of the fourth semiconductor chip 4 may be similar to the structure of the first semiconductor chip 1. The fourth semiconductor chip 4 has a first surface 41 (e.g., a bottom surface), a second surface 42 (e.g., a top surface) and a lateral surface 43 extending between the first surface 41 (e.g., the bottom surface) and the second surface 42 (e.g., the top surface).

The fourth semiconductor chip 4 may include a fourth base portion 40, a fourth conductive structure 44 and a fourth lower structure 45 that are same as the first base portion 10, the first conductive structure 14 and the first lower structure 15 of the first semiconductor chip 1, respectively.

The first surface 41 of the fourth semiconductor chip 4 may directly contact the third intermediate structure 73. The fourth lower dielectric layer 451 of the fourth lower structure 45 of the fourth semiconductor chip 4 may be adhered to the dielectric layer 731 of the third intermediate structure 73. The fourth lower pads 452 of the fourth lower structure 45 of the fourth semiconductor chip 4 may be attached to the hybrid bonding pads 7324 of the third intermediate structure 73 by metal-to-metal bonding. Thus, the hybrid bonding pads 7324 of the third intermediate structure 73 physically connect and electrically connect the fourth semiconductor chip 4 and the third semiconductor chip 3.

Then, a fourth encapsulant 48 may be formed or disposed on the top surface of the third intermediate structure 73 to encapsulate the fourth semiconductor chips 4. Thus, the fourth semiconductor chip 4 may be encapsulated by the fourth encapsulant 48. A material of the fourth encapsulant 48 may include a molding compound with or without fillers. The fourth encapsulant 48 may cover and contact the lateral surface 43 of the fourth semiconductor chip 4.

Meanwhile, the fourth semiconductor chip 4 is disposed over the third semiconductor chip 3. The third intermediate structure 73 is interposed between the fourth semiconductor chip 4 and the third semiconductor chip 3, and between the fourth encapsulant 48 and the third encapsulant 38. The periphery portion 7323 of the third rigid layer 732 may vertically overlap the fourth encapsulant 48 and the third encapsulant 38, and is configured to control a warpage of the electronic device 6. The periphery portion 7323 of the third rigid layer 732 may directly contact the fourth encapsulant 48 and the third encapsulant 38. In addition, the outer portion 7313 of the dielectric layer 731 may directly contact the fourth encapsulant 48 and the third encapsulant 38.

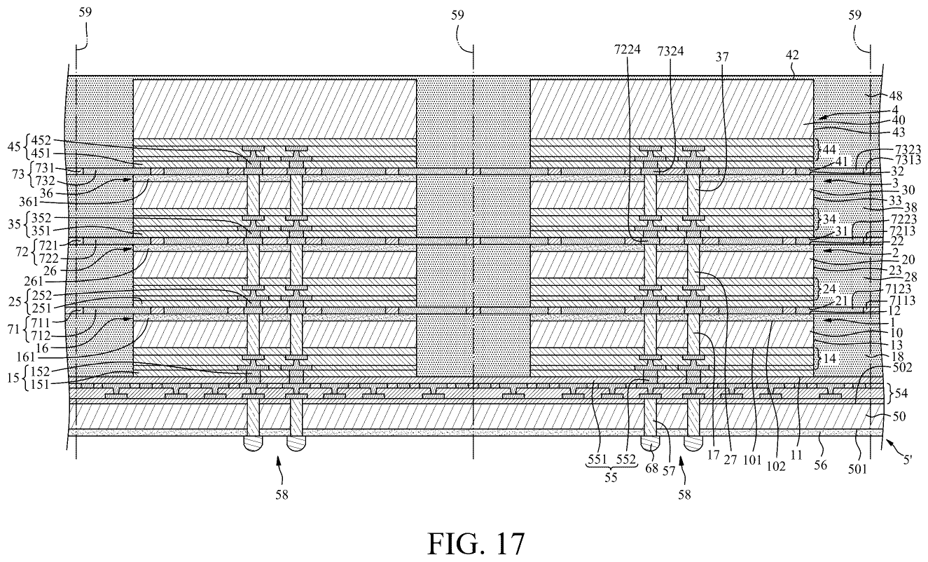

With reference to FIG. 17, the fifth base portion 50 may be thinned from its first surface 501 (e.g., the bottom surface) by grinding, chemical-mechanical Polishing (CMP) and etching, so as to expose the fifth conductive vias 57. Thus, the fifth conductive vias 57 may extend beyond the first surface 501 (e.g., the bottom surface) of the fifth base portion 50. The fifth conductive vias 57 may extend through the fifth base portion 50. A length of the fifth conductive via 57 may be greater than a thickness of the fifth base portion 50.

Then, a dielectric layer 56 may be formed or disposed on the first surface 501 (e.g., the bottom surface) of the fifth base portion 50, and may encapsulate the fifth conductive vias 57. Then, a plurality of external connectors 68 may be formed on or in the dielectric layer 56 to connect the fifth conductive vias 57 for external connection.

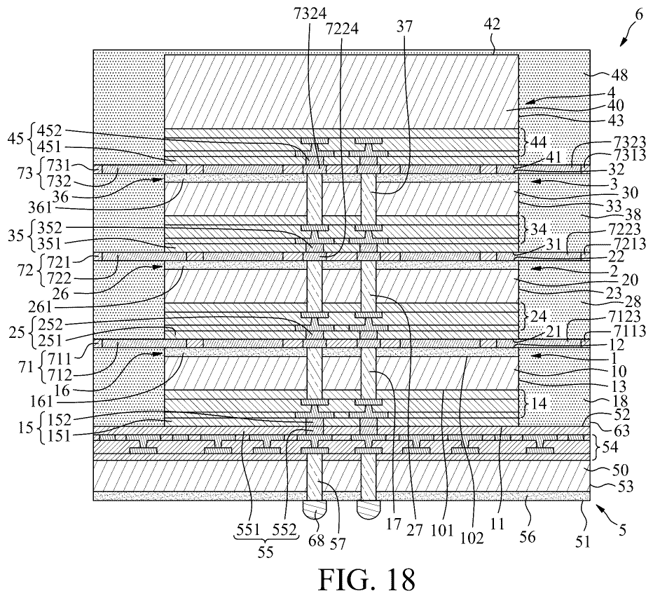

With reference to FIG. 18, a singulation process may be conducted along the singulation lines 59 to form a plurality of electronic devices 6.

With reference to FIG. 18, a schematic cross-sectional view of an electronic device 6 according to one embodiment of the present disclosure is illustrated. For example, the electronic device 6 may be a high bandwidth memory (HBM).

In some embodiments, the electronic device 6 may include a first semiconductor chip 1, a first encapsulant 18, a first intermediate structure 71, a second semiconductor chip 2, a second encapsulant 28, a second intermediate structure 72, a third semiconductor chip 3, a third encapsulant 38, a third intermediate structure 73, a fourth semiconductor chip 4, a fourth encapsulant 48, a base semiconductor chip 5 and a plurality of external connectors 68.

The first semiconductor chip 1 may have a bottom surface 11 (e.g., a first surface), a top surface 12 (e.g., a second surface) and a lateral surface 13 extending between the bottom surface 11 and the top surface 12. The first semiconductor chip 1 may include a first base portion 10, a first conductive structure 14, a first lower structure 15, a first upper structure 16 and a plurality of first conductive vias 17. The first semiconductor chip 1 may be a memory chip such as a dynamic random access memory (DRAM) chip.

The first conductive structure 14 may be disposed on the first surface 101 (e.g., a bottom surface) of the first base portion 10. The first conductive vias 17 may extend through the first base portion 10, and may be electrically connected to the first conductive structure 14.

In some embodiments, a bottom end of the first conductive vias 17 may extend beyond the first surface 101 (e.g., the bottom surface) of the first base portion 10, and may extend into the first conductive structure 14. Thus, the first conductive via 17 may be a monolithic structure, and a length of the first conductive via 17 may be greater than a thickness of the first base portion 10. In some embodiments, the first conductive via 17 may extend beyond the second surface 102 (e.g., the top surface) of the first base portion 10.

The first lower structure 15 may be disposed on the first conductive structure 14. The first lower structure 15 may be a hybrid bonding (HB) structure or a solder bonding structure, and may include a first lower dielectric layer 151 and a plurality of first lower pads 152. The first lower dielectric layer 151 may be a hybrid bonding (HB) dielectric layer. Each of the first lower pads 152 may be a hybrid bonding (HB) pad. The first lower pads 152 may be embedded in the first lower dielectric layer 151, and may be exposed by the first lower dielectric layer 151. The first lower pads 152 may be surrounded by the first lower dielectric layer 151. The first lower pads 152 may be electrically connected to the first conductive vias 17 through the first conductive structure 14.

In some embodiments, a bottom surface of the first lower pad 152 may be substantially aligned with a bottom surface of the first lower dielectric layer 151. Thus, the bottom surface of the first lower pad 152 may be exposed by the bottom surface of the first lower dielectric layer 151. In some embodiments, a top surface of the first lower pad 152 may be substantially aligned with a top surface of the first lower dielectric layer 151. Thus, the top surface of the first lower pad 152 may contact the first conductive structure 14. In some embodiments, a thickness of the first lower pad 152 may be substantially equal to a thickness of the first lower dielectric layer 151.

The first upper structure 16 may be disposed on the second surface 102 (e.g., the top surface) of the first base portion 10. The first upper structure 16 may include a first upper dielectric layer 161.

The first encapsulant 18 may encapsulate the first semiconductor chip 1. The first intermediate structure 71 may be formed or disposed on the first upper structure 16 (e.g., the first upper dielectric layer 161) of the first semiconductor chip 1 and the first encapsulant 18. The first intermediate structure 71 may be a warpage control structure and a hybrid bonding (HB) structure. The first intermediate structure 71 may include a dielectric layer 711 and a first rigid layer 712. The dielectric layer 711 may be a hybrid bonding (HB) dielectric layer, and may include SiO₂, SiN, and/or SiCN. The dielectric layer 711 may encapsulate the first rigid layer 712. A material of the first rigid layer 712 of the first intermediate structure 71 may include metal such as copper (Cu).

The first rigid layer 712 may include a plurality of hybrid bonding pads 7124, a middle portion 7125 and a periphery portion 7123. The hybrid bonding pads 7124 may be disposed on the first conductive vias 17 for electrical connection. The hybrid bonding pads 7124 may directly contact the first conductive vias 17. Thus, the first conductive vias 17 may be electrically connected to the first rigid layer 712 of the first intermediate structure 71.

The periphery portion 7123 may extend beyond the lateral surface 13 of the first semiconductor chip 1. Thus, the periphery portion 7123 may vertically overlap or may directly contact the first upper structure 16 (e.g., the first upper dielectric layer 161) and the first encapsulant 18. The middle portion 7125 and the periphery portion 7123 may be dummy. That is, the middle portion 7125 and the periphery portion 7123 may have no electrical function. In addition, the dielectric layer 711 may include an outer portion 7113 surrounding the periphery portion 7123 and directly contacting the first encapsulant 18.

The second semiconductor chip 2 may be stacked on the first intermediate structure 71, and may be electrically connected to the first semiconductor chip 1 by hybrid bonding or metal-to-metal bonding through the hybrid bonding pads 7124 of the first intermediate structure 71. The second semiconductor chip 2 may have a bottom surface 21 (e.g., a first surface), a top surface 22 (e.g., a second surface) and a lateral surface 23 extending between the bottom surface 21 and the top surface 22. The lateral surface 23 of the second semiconductor chip 2 may be substantially aligned with the lateral surface 13 of the first semiconductor chip 1.

The second semiconductor chip 2 may include a second base portion 20, a second conductive structure 24, a second lower structure 25, a second upper structure 26 and a plurality of second conductive vias 27. The second semiconductor chip 2 may be a memory chip such as a dynamic random access memory (DRAM) chip.

The second conductive structure 24 may be disposed on the first surface (e.g., a bottom surface) of the second base portion 20. The second conductive vias 27 may extend through the second base portion 20, and may be electrically connected to the second conductive structure 24. In some embodiments, a bottom end of the second conductive vias 27 may extend beyond the first surface (e.g., the bottom surface) of the second base portion 20, and may extend into the second conductive structure 24. Thus, the second conductive via 27 may be a monolithic structure, and a length of the second conductive via 27 may be greater than a thickness of the second base portion 20. In some embodiments, the second conductive via 27 may extend beyond the second surface (e.g., the top surface) of the second base portion 20.

The second lower structure 25 may be disposed on the second conductive structure 24. The second lower structure 25 may be a hybrid bonding (HB) structure, and may include a second lower dielectric layer 251 and a plurality of second lower pads 252. The second lower dielectric layer 251 may be a hybrid bonding (HB) dielectric layer. Each of the second lower pads 252 may be a hybrid bonding (HB) pad. The second lower pads 252 may be embedded in the second lower dielectric layer 251, and may be exposed by the second lower dielectric layer 251. The second lower pads 252 may be surrounded by the second lower dielectric layer 251. The second lower pads 252 may be electrically connected to the second conductive vias 27 through the second conductive structure 24.

In some embodiments, a bottom surface of the second lower pad 252 may be substantially aligned with a bottom surface of the second lower dielectric layer 251. Thus, the bottom surface of the second lower pad 252 may be exposed by the bottom surface of the second lower dielectric layer 251. In some embodiments, a top surface of the second lower pad 252 may be substantially aligned with a top surface of the second lower dielectric layer 251. Thus, the top surface of the second lower pad 252 may contact the second conductive structure 24. In some embodiments, a thickness of the second lower pad 252 may be substantially equal to a thickness of the second lower dielectric layer 251.

The second lower structure 25 of the second semiconductor chip 2 may be bonded to and electrically connected to the first intermediate structure 71 through hybrid bonding. Thus, the second lower pad 252 of the second semiconductor chip 2 may directly contact the hybrid bonding pads 7124 of the first intermediate structure 71.

The second upper structure 26 may be disposed on the second surface (e.g., the top surface) of the second base portion 20. The second upper structure 26 may be a hybrid bonding (HB) structure or a solder bonding structure, and may include a second upper dielectric layer 261. The second upper dielectric layer 261 may be a hybrid bonding (HB) dielectric layer.

In some embodiments, the bottom surface 21 of the second semiconductor chip 2 may include the bottom surface of the second lower pad 252 and the bottom surface of the second lower dielectric layer 251. The top surface 22 of the second semiconductor chip 2 may include the top surfaces of the second conductive vias 27 and the top surface of the second upper dielectric layer 261. The lateral surface 23 of the second semiconductor chip 2 may include a lateral surface of the second base portion 20, a lateral surface of the second conductive structure 24, a lateral surface of the second lower structure 25 and a lateral surface of the second upper structure 26.

The second encapsulant 28 may encapsulate the second semiconductor chip 2. The second intermediate structure 72 may be formed or disposed on the second upper structure 26 (e.g., the second upper dielectric layer 261) of the second semiconductor chip 2 and the second encapsulant 28. The second intermediate structure 72 may be a warpage control structure and a hybrid bonding (HB) structure. The second intermediate structure 72 may include a dielectric layer 721 and a second rigid layer 722. The dielectric layer 721 may be a hybrid bonding (HB) dielectric layer, and may include SiO₂, SiN, and/or SiCN. The dielectric layer 721 may encapsulate the second rigid layer 722. A material of the second rigid layer 722 of the second intermediate structure 72 may include metal such as copper (Cu).

The second rigid layer 722 may include a plurality of hybrid bonding pads 7224, a middle portion and a periphery portion 7223. The hybrid bonding pads 7224 may be disposed on the second conductive vias 27 for electrical connection. The hybrid bonding pads 7224 may directly contact the second conductive vias 27.

The periphery portion 7223 may extend beyond the lateral surface 23 of the second semiconductor chip 2. Thus, the periphery portion 7223 may vertically overlap or may directly contact the second upper structure 26 (e.g., the second upper dielectric layer 261) and the second encapsulant 28. The middle portion and the periphery portion 7223 may be dummy. That is, the middle portion and the periphery portion 7223 may have no electrical function.

The third semiconductor chip 3 may be stacked on electrically connected to the second intermediate structure 72 by hybrid bonding or metal-to-metal bonding through the hybrid bonding pads 7224 of the second intermediate structure 72. The third semiconductor chip 3 may have a bottom surface 31 (e.g., a first surface), a top surface 32 (e.g., a second surface) and a lateral surface 33 extending between the bottom surface 31 and the top surface 32.

The third semiconductor chip 3 may include a third base portion 30, a third conductive structure 34, a third lower structure 35, a third upper structure 36 and a plurality of third conductive vias 37. The third semiconductor chip 3 may be a memory chip such as a dynamic random access memory (DRAM) chip.

The third base portion 30 may have a first surface (e.g., a bottom surface) and a second surface (e.g., a top surface) opposite to the first surface. The third conductive structure 34 may be disposed on the first surface (e.g., a bottom surface) of the third base portion 30.

The third conductive vias 37 may extend through the third base portion 30, and may be electrically connected to the third conductive structure 34. In some embodiments, a bottom end of the third conductive vias 37 may extend beyond the first surface (e.g., the bottom surface) of the third base portion 30, and may extend into the third conductive structure 34. In some embodiments, the third conductive via 37 may extend beyond the second surface (e.g., the top surface) of the third base portion 30.

The third lower structure 35 may be disposed on the third conductive structure 34. The third lower structure 35 may be a hybrid bonding (HB) structure or a solder bonding structure, and may include a third lower dielectric layer 351 and a plurality of third lower pads 352. The third lower dielectric layer 351 may be a hybrid bonding (HB) dielectric layer. Each of the third lower pads 352 may be a hybrid bonding (HB) pad. The third lower pads 352 may be embedded in the third lower dielectric layer 351, and may be exposed by the third lower dielectric layer 351. The third lower pads 352 may be electrically connected to the third conductive vias 37 through the third conductive structure 34.

The third lower pads 352 of the third lower structure 35 of the third semiconductor chip 3 may be attached to the hybrid bonding pads 7224 of the second intermediate structure 72 by metal-to-metal bonding.

The third upper structure 36 may be disposed on the second surface (e.g., the top surface) of the third base portion 30. The third upper structure 36 may be a hybrid bonding (HB) structure, and may include a third upper dielectric layer 361. The third upper dielectric layer 361 may be a hybrid bonding (HB) dielectric layer.

The third encapsulant 38 may encapsulate the third semiconductor chip 3. The third intermediate structure 73 may be formed or disposed on the third upper structure 36 (e.g., the third upper dielectric layer 361) of the third semiconductor chip 3 and the third encapsulant 38. The third intermediate structure 73 may be a warpage control structure and a hybrid bonding (HB) structure. The third intermediate structure 73 may include a dielectric layer 731 and a third rigid layer 732. The dielectric layer 731 may be a hybrid bonding (HB) dielectric layer, and may include SiO₂, SiN, and/or SiCN. The dielectric layer 731 may encapsulate the third rigid layer 732. A material of the third rigid layer 732 of the third intermediate structure 73 may include metal such as copper (Cu).

The third rigid layer 732 may include a plurality of hybrid bonding pads 7324, a middle portion and a periphery portion 7323. The hybrid bonding pads 7324 may be disposed on the third conductive vias 37 for electrical connection. The hybrid bonding pads 7324 may directly contact the third conductive vias 37.

The periphery portion 7323 may extend beyond the lateral surface 33 of the second semiconductor chip 2. Thus, the periphery portion 7323 may vertically overlap or may directly contact the third upper structure 36 (e.g., the third upper dielectric layer 361) and the third encapsulant 38. The middle portion and the periphery portion 7323 may be dummy. That is, the middle portion and the periphery portion 7323 may have no electrical function.

The fourth semiconductor chip 4 may be stacked on and electrically connected the third intermediate structure 73 by hybrid bonding or metal-to-metal bonding through the hybrid bonding pads 7324 of the third intermediate structure 73. The fourth semiconductor chip 4 may have a bottom surface 41 (e.g., a first surface), a top surface 42 (e.g., a second surface) and a lateral surface 43 extending between the bottom surface 41 and the top surface 42.

The fourth semiconductor chip 4 may include a fourth base portion 40, a fourth conductive structure 44 and a fourth lower structure 45. The fourth semiconductor chip 4 may be a memory chip such as a dynamic random access memory (DRAM) chip.

The fourth conductive structure 44 may be disposed on the first surface (e.g., a bottom surface) of the fourth base portion 40. The fourth lower structure 45 may be disposed on the fourth conductive structure 44. The fourth lower structure 45 may be a hybrid bonding (HB) structure, and may include a fourth lower dielectric layer 451 and a plurality of fourth lower pads 452. The fourth lower dielectric layer 451 may be a hybrid bonding (HB) dielectric layer. Each of the fourth lower pads 452 may be a hybrid bonding (HB) pad. The fourth lower pads 452 may be embedded in the fourth lower dielectric layer 451, and may be exposed by the fourth lower dielectric layer 451.

The fourth lower structure 45 of the fourth semiconductor chip 4 may be bonded to and electrically connected to the third intermediate structure 73 through hybrid bonding. For example, the fourth lower dielectric layer 451 of the fourth semiconductor chip 4 may be bonded to the dielectric layer 731 of the third intermediate structure 73 through dielectric-to-dielectric bonding. The fourth lower pad 452 of the fourth semiconductor chip 4 may be attached to, joined to, or electrically connected to the hybrid bonding pads 7324 of the third intermediate structure 73 through metal-to-metal bonding. The fourth encapsulant 48 may encapsulate the fourth semiconductor chip 4.

The base semiconductor chip 5 (or a fifth semiconductor chip 5) may have a bottom surface 51 (e.g., a first surface), a top surface 52 (e.g., a second surface) and a lateral surface 53 extending between the bottom surface 51 and the top surface 52. The base semiconductor chip 5 may include a fifth base portion 50, a fifth conductive structure 54, a fifth upper structure 55, a plurality of fifth conductive vias 57 and a dielectric layer 56. The base semiconductor chip 5 may be a controller chip such as an application processor (AP) chip.

The fifth conductive structure 54 may be disposed on the first surface (e.g., the top surface) of the fifth base portion 50. The fifth conductive vias 57 may extend through the fifth base portion 50, and may be electrically connected to the fifth conductive structure 54. In some embodiments, an end of the fifth conductive via 57 may extend into the fifth conductive structure 54.

The fifth upper structure 55 may be disposed on the fifth conductive structure 54. The fifth upper structure 55 may be a hybrid bonding (HB) structure or a solder bonding structure, and may include a fifth upper dielectric layer 551 and a plurality of fifth upper pads 552. The fifth upper dielectric layer 551 may be a hybrid bonding (HB) dielectric layer. Each of the fifth upper pads 552 may be a hybrid bonding (HB) pad. The fifth upper pads 552 may be embedded in the fifth upper dielectric layer 551, and may be exposed by the fifth upper dielectric layer 551.

The dielectric layer 56 may be formed or disposed on the first surface (e.g., the bottom surface) of the fifth base portion 50, and may encapsulate the fifth conductive vias 57. The first lower pads 152 of the first lower structure 15 of the first semiconductor chip 1 may be bonded to and electrically connected to the fifth upper pad 552 of the fifth upper structure 55 of the base semiconductor chip 5 through hybrid bonding.

The first encapsulant 18 may be disposed on or may directly contact the top surface 52 (e.g., the second surface) of the base semiconductor chip 5. Thus, the lateral surface 53 of the base semiconductor chip 5, the lateral surface of the first encapsulant 18, the lateral surface of the second encapsulant 28, the lateral surface of the third encapsulant 38 and the lateral surface of the fourth encapsulant 48 may be substantially aligned with each other so as to form the lateral surface 63 of the electronic device 6. The external connectors 68 may be formed in or on the dielectric layer 56 to connect the fifth conductive vias 57 for external connection. The external connectors 68 may include a reflowable material such as AgSn. Thus, the external connectors 68 may include solder balls, solder bumps or micro-bumps. The external connectors 68 may be disposed on the fifth conductive vias 57.

In the embodiment illustrated in FIG. 18, a rigidity of the first rigid layer 712 of the first intermediate structure 71 is greater than a rigidity of the first encapsulant 18 and a rigidity of the second encapsulant 28. A rigidity of the second rigid layer 722 of the second intermediate structure 72 is greater than the rigidity of the second encapsulant 28 and a rigidity of the third encapsulant 38. A rigidity of the third rigid layer 732 of the third intermediate structure 73 is greater than the rigidity of the third encapsulant 38 and a rigidity of the fourth encapsulant 48. Thus, the first rigid layer 712 of the first intermediate structure 71, the second rigid layer 722 of the second intermediate structure 72 and the third rigid layer 732 of the third intermediate structure 73 may be configured to control or reduce the warpage of the electronic device 6. As a result, the bondings between the first semiconductor chip 1, the second semiconductor chip 2, the third semiconductor chip 3 and the fourth semiconductor chip 4 may be enhanced, and the risks of delamination between the first semiconductor chip 1, the second semiconductor chip 2, the third semiconductor chip 3 and the fourth semiconductor chip 4 may be reduced. Therefore, the reliability and working life of the electronic device 6 may be improved.

FIG. 19 illustrates, in a schematic cross-sectional view diagram, a semiconductor structure 8 in accordance with one embodiment of the present disclosure. The semiconductor structure 8 may include an interposer 80 (or a substrate 80), an electronic device 6, a semiconductor device 82 and a plurality of external connectors 84.

The interposer 80 may include a base portion, a conductive structure and a plurality of conductive through vias. The base portion may be a semiconductor substrate, and may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials. In some embodiments, the substrate 80 may be a printed circuit board (PCB).

The conductive structure may be disposed on the base portion. In some embodiments, the conductive structure may include a redistribution layer (RDL) structure. The conductive through vias may extend through the base portion, and may be electrically connected to the conductive structure.

The external connectors 84 may be disposed on the bottom surface of the interposer 80 for external connection. The external connectors 84 may include a reflowable material such as AgSn. Thus, the external connectors 84 may include solder balls, solder bumps or micro-bumps. The external connectors 84 may be disposed on the conductive through vias.

The electronic device 6 of FIG. 19 may be the electronic device 6 of FIG. 18. The electronic device 6 may be bonded to and electrically connected to the interposer 80 through the external connectors 68.

The semiconductor device 82 may be a logic chip or a logic die. The semiconductor device 82 may be bonded to and electrically connected to the interposer 80 through a plurality of solders 83. Thus, the electronic device 6 may be electrically connected to or communicated with the semiconductor device 82 through the interposer 80.

FIG. 20 illustrates, in a schematic cross-sectional view diagram, an electronic device 6a in accordance with one embodiment of the present disclosure. The structure of the electronic device 6a of FIG. 20 is similar to the structure of the electronic device 6 of FIG. 18, and the difference therebetween is described as follows. As shown in FIG. 20, the second lower structure 25′ may further include a plurality of dummy pads 253 surrounding the second lower pads 252. The dummy pads 253 may be embedded in the second lower dielectric layer 251, and may be connected to and bonded to the middle portion 7125 and the periphery portion 7123 of the first rigid layer 712 during the hybrid bonding process, so as to enhance the bonding between the first semiconductor chip 1 and the second semiconductor chip 2.

The third lower structure 35′ may further include a plurality of dummy pads 353 surrounding the third lower pads 352. The dummy pads 353 may be embedded in the third lower dielectric layer 351, and may be connected to and bonded to the middle portion and the periphery portion 7223 of the second rigid layer 722 during the hybrid bonding process, so as to enhance the bonding between the third semiconductor chip 3 and the second semiconductor chip 2.

The fourth lower structure 45′ may further include a plurality of dummy pads 453 surrounding the fourth lower pads 452. The dummy pads 453 may be embedded in the fourth lower dielectric layer 451, and may be connected to and bonded to the middle portion and the periphery portion 7323 of the third rigid layer 732 during the hybrid bonding process, so as to enhance the bonding between the fourth semiconductor chip 4 and the third semiconductor chip 3.

FIG. 21 illustrates, in a schematic cross-sectional view diagram, an electronic device 6b in accordance with one embodiment of the present disclosure. The structure of the electronic device 6b of FIG. 21 is similar to the structure of the electronic device 6 of FIG. 18, and the difference therebetween is described as follows. As shown in FIG. 21, the electronic device 6b may include a first assembly 6′ and a second assembly 6″. The first assembly 6′ may include a first semiconductor chip 1, a second semiconductor chip 2 and an encapsulant 28b. The first semiconductor chip 1 and the second semiconductor chip 2 of FIG. 21 may be same as or similar to the first semiconductor chip 1 and the second semiconductor chip 2 of FIG. 18, respectively. The second semiconductor chip 2 may be stacked on the first semiconductor chip 1, and may be electrically connected to the first semiconductor chip 1 by hybrid bonding. The first intermediate structure 71 of FIG. 18 may be omitted. The first surface 21 (e.g., the bottom surface) of the second semiconductor chip 2 may directly contact the second surface 12 (e.g., the top surface) of the first semiconductor chip 1. The encapsulant 28b may encapsulate the first semiconductor chip 1 and the second semiconductor chip 2.

The second assembly 6″ may include a third semiconductor chip 3, a fourth semiconductor chip 4 and an encapsulant 48b. The third semiconductor chip 3 and the fourth semiconductor chip 4 of FIG. 21 may be same as or similar to the third semiconductor chip 3 and the fourth semiconductor chip 4 of FIG. 18, respectively. The fourth semiconductor chip 4 may be stacked on the third semiconductor chip 3, and may be electrically connected to the third semiconductor chip 3 by hybrid bonding. The third intermediate structure 73 of FIG. 18 may be omitted. The first surface 41 (e.g., the bottom surface) of the fourth semiconductor chip 4 may directly contact the second surface 32 (e.g., the top surface) of the third semiconductor chip 3. The encapsulant 48b may encapsulate the third semiconductor chip 3 and the fourth semiconductor chip 4.

The second intermediate structure 72 may be interposed between the first assembly 6′ and the second assembly 6″. The second intermediate structure 72 may include a dielectric layer 721 and a second rigid layer 722 (e.g., a second metal layer). The dielectric layer 721 may encapsulate the second rigid layer 722 (e.g., the second metal layer). An outer portion 7213 of the dielectric layer 721 may directly contact the encapsulant 28b of the first assembly 6′ and the encapsulant 48b of the second assembly 6″.

The second rigid layer 722 (e.g., the second metal layer) may be interposed between the first assembly 6′ and the second assembly 6″. The second rigid layer 722 (e.g., the second metal layer) may include a plurality of hybrid bonding pads 7224, a middle portion and a periphery portion 7223. The hybrid bonding pads 7224 of the second rigid layer 722 may be configured to electrically connect the second semiconductor chip 2 and the third semiconductor chip 3. The periphery portion 7223 of the second rigid layer 722 (e.g., the second metal layer) may directly contact the encapsulant 28b of the first assembly 6′ and the encapsulant 48b of the second assembly 6″.

FIG. 22 illustrates, in a schematic cross-sectional view diagram, an electronic device 6c in accordance with one embodiment of the present disclosure. The structure of the electronic device 6c of FIG. 22 is similar to the structure of the electronic device 6b of FIG. 21, and the difference therebetween is described as follows. As shown in FIG. 22, the third lower structure 35′ of the third semiconductor chip 3 may further include a plurality of dummy pads 353 surrounding the third lower pads 352. The dummy pads 353 may be embedded in the third lower dielectric layer 351, and may be connected to and bonded to the middle portion and the periphery portion 7223 of the second rigid layer 722 (e.g., the second metal layer) during the hybrid bonding process, so as to enhance the bonding between the third semiconductor chip 3 and the second semiconductor chip 2.

One aspect of the present disclosure provides an electronic device including a first semiconductor chip, a second semiconductor chip and a first intermediate structure. The first semiconductor chip is encapsulated by a first encapsulant. The second semiconductor chip is disposed over and electrically connected to the first semiconductor chip. The second semiconductor chip is encapsulated by a second encapsulant. The first intermediate structure is interposed between the first semiconductor chip and the second semiconductor chip, and includes a first rigid layer. A periphery portion of the first rigid layer of the first intermediate structure vertically overlaps the first encapsulant and the second encapsulant, and is configured to control a warpage of the electronic device.

Another aspect of the present disclosure provides an electronic device including a first assembly, a second assembly and a metal layer. The first assembly includes a first semiconductor chip and a second semiconductor chip stacked on the first semiconductor chip. The second semiconductor chip is electrically connected to the first semiconductor chip by hybrid bonding. The second assembly includes a third semiconductor chip and a fourth semiconductor chip stacked on the third semiconductor chip. The fourth semiconductor chip is electrically connected to the third semiconductor chip by hybrid bonding. The metal layer is interposed between the first assembly and the second assembly. A periphery portion of the metal layer directly contacts an encapsulant of the first assembly and an encapsulant of the second assembly.

Another aspect of the present disclosure provides a method for manufacturing an electronic device including: providing a first semiconductor chip; forming a first encapsulant to encapsulate the first semiconductor chip; forming a first intermediate structure on the first semiconductor chip and the first encapsulant; providing a second semiconductor chip on the first intermediate structure; and forming a second encapsulant on the first intermediate structure to encapsulate the second semiconductor chip.

Due to the design of the electronic device of the present disclosure, the first rigid layer or the metal layer are configured to control or reduce the warpage of the electronic device. As a result, the bonding between the first semiconductor chip and the second semiconductor chip, or the bonding between the first assembly and the second assembly is enhanced. The risk of delamination between the first semiconductor chip and the second semiconductor chip, or the risk of delamination between the first assembly and the second assembly is reduced. Therefore, the reliability and working life of the electronic device is improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. An electronic device, comprising:
a first semiconductor chip encapsulated by a first encapsulant;
a second semiconductor chip disposed over and electrically connected to the first semiconductor chip, wherein the second semiconductor chip is encapsulated by a second encapsulant; and
a first intermediate structure interposed between the first semiconductor chip and the second semiconductor chip, and including a first rigid layer, wherein a periphery portion of the first rigid layer of the first intermediate structure vertically overlaps the first encapsulant and the second encapsulant, and is configured to control a warpage of the electronic device.

2. The electronic device of claim 1, wherein the periphery portion of the first rigid layer of the first intermediate structure directly contacts the first encapsulant and the second encapsulant.

3. The electronic device of claim 1, wherein a material of the first rigid layer of the first intermediate structure includes metal.

4. The electronic device of claim 1, wherein both of a material of the first semiconductor chip and a material of the second semiconductor chip include silicon, wherein both of a material of the first encapsulant and a material of the second encapsulant include molding compound.

5. The electronic device of claim 1, wherein the first rigid layer of the first intermediate structure further includes a plurality of hybrid bonding pads connecting the first semiconductor chip and the second semiconductor chip.

6. The electronic device of claim 5, wherein the periphery portion and the plurality of hybrid bonding pads are formed concurrently.

7. The electronic device of claim 5, wherein a top surface of the periphery portion is substantially level with a plurality of top surfaces of the plurality of hybrid bonding pads.

8. The electronic device of claim 5, wherein the periphery portion surrounds the plurality of hybrid bonding pads.

9. The electronic device of claim 1, wherein the periphery portion is in a ring shape from a top view.

10. The electronic device of claim 1, wherein the periphery portion includes a plurality of sections arranged in a plurality of rows.

11. The electronic device of claim 1, wherein the first intermediate structure further includes a dielectric layer encapsulating the first rigid layer.

12. The electronic device of claim 11, wherein the dielectric layer is a hybrid bonding (HB) dielectric layer.

13. The electronic device of claim 11, wherein a portion of the dielectric layer directly contacts the first encapsulant and the second encapsulant.

14. The electronic device of claim 11, wherein a top surface of the dielectric layer is substantially level with a top surface of the first rigid layer.

15. The electronic device of claim 1, wherein the first semiconductor chip further includes:
a first base portion;
a first conductive structure disposed on a first surface of the first base portion;
a first lower structure disposed on the first conductive structure; and
a first upper structure disposed on a second surface of the first base portion opposite to the first surface of the first base portion.

16. The electronic device of claim 15, wherein the first semiconductor chip further includes a plurality of first conductive vias extending through the first base portion, wherein the first lower structure includes a first lower dielectric layer and a plurality of first lower pads embedded in and exposed by the first lower dielectric layer, and the plurality of first lower pads are electrically connected to the plurality of first conductive vias through the first conductive structure.

17. The electronic device of claim 16, wherein the plurality of first conductive vias extend into the first conductive structure.

18. The electronic device of claim 16, wherein the first upper structure includes a first upper dielectric layer, and the first intermediate structure is disposed on the first upper dielectric layer.

19. The electronic device of claim 18, wherein the plurality of first conductive vias extend through the first upper structure and are electrically connected to the first intermediate structure.

20. The electronic device of claim 1, wherein the periphery portion of the first rigid layer of the first intermediate structure is dummy.
